(19) United States
(12) Patent Application Publication
(10) Pub. No.: US 2024/0234179 A9
(43) Pub. Date: Jul. 11, 2024

(54) LIGHT-EMITTING ELEMENT TRANSFER SYSTEM

(71) Applicant: Samsung Display Co., LTD., Yongin-si (KR)

(72) Inventors: Jeong Won HAN, Yongin-si (KR); Chung Sic CHOI, Yongin-si (KR); Won Hee OH, Yongin-si (KR); Han Chun RYU, Yongin-si (KR); Jae Woo LEE, Yongin-si (KR)

(21) Appl. No.: 18/224,973

(22) Filed: Jul. 21, 2023

(30) Foreign Application Priority Data
Oct. 24, 2022 (KR) 10/2022-0137021

(51) Int. Cl. H01L 21/67; H01L 21/677

(52) U.S. Cl. CPC H01L 21/67132; H01L 21/67144; H01L 21/67265; H01L 21/67766; H01L 25/167

(57) ABSTRACT

A light-emitting element transfer system includes raw film cutting device for forming a transfer member by cutting a raw film, a stretching device for stretching a transfer film with a plurality of light-emitting elements disposed thereon, a circuit board support member for supporting a circuit board and transport head for adsorbing the transfer member and transferring the light-emitting elements on the transfer film onto the circuit board by using the adsorbed transfer member.

This application claims priority to Korean Patent Application No. 10-2022-0137021, filed on Oct. 24, 2022, and all the benefits accruing therefrom under 35 U.S.C. § 119, the content of which in its entirety is herein incorporated by reference.

### BACKGROUND

### 1. Field

The present disclosure relates to a light-emitting element transfer system.

### 2. Description of the Related Art

Display devices are becoming more important with developments in multimedia technology. Accordingly, various display devices such as an organic light-emitting diode (“OLED”) display device, a liquid crystal display (“LCD”) device, and the like have been used.

Typically, a display device includes a display panel such as a light-emitting display panel or an LCD panel. The light-emitting display panel may include light-emitting elements such as, for example, light-emitting diodes (“LEDs”). Examples of the LEDs include organic LEDs (“OLEDs”) using an organic material as a fluorescent material and inorganic LEDs using an inorganic material as a fluorescent material.

To fabricate a display panel using inorganic LEDs, transfer equipment for transferring micro-LEDs on the substrate of a display panel needs to be developed.

### SUMMARY

Aspects of the present disclosure provide a light-emitting element transfer system, which fabricates a disposable transfer member and transfers light-emitting elements on a transfer film onto a circuit substrate by using the disposable transfer member.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a light-emitting element transfer system includes raw film cutting device for forming a transfer member by cutting a raw film, a stretching device for stretching a transfer film with a plurality of light-emitting elements disposed thereon, a circuit board support member for supporting a circuit board and transport head for adsorbing the transfer member and transferring the light-emitting elements on the transfer film onto the circuit board by using the adsorbed transfer member.

The transfer member may include a base layer and a stamp layer, which is disposed on one surface of the base layer, and the stamp layer is formed of an adhesive or sticky material.

The transfer member may further include a protective film, which is disposed on one surface of the stamp layer, and the light-emitting element transfer system further includes a peeling robot configured to peel off the protective film of the transfer member adsorbed by the transport head.

The peeling robot may peel off the protective film from the stamp layer of the transfer member by using a tape having an adhesive surface, and the light-emitting element transfer system further includes a tape dispenser for providing the tape.

The raw film cutting device may include a pedestal for supporting the raw film, a raw film transport unit disposed on opposite sides of the pedestal and for transporting the raw film in a first direction, and a cutting unit for cutting the raw film on the pedestal, and the base layer, the stamp layer, and the protective film of the transfer member are sequentially disposed on the pedestal.

The raw film cutting device may further include a first vision unit for capturing an image of the transfer member and the raw film on the pedestal.

The light-emitting element transfer system may include a reversing device for turning the transfer member upside down and left to right by adsorbing the protective film of the transfer member on the pedestal.

The reversing device may be rotatable 180 degrees about a rotational shaft, and the reversing device may further include a stage including a support chuck capable of adsorbing one surface of the transfer member.

The light-emitting element transfer system may include a first transport rail disposed under the pedestal and the raw film cutting device, where the pedestal may be movable along the first transport rail.

The transport head may include a body part movable along a second transport rail, a head chuck disposed on one surface of the body part and for adsorbing or detaching the transfer member, and at least one second vision unit for capturing an image of the transfer member on the reversing device.

The second transport rail may include a first-direction transport rail extending in the first direction, a second-direction transport rail extending in a second direction, which is perpendicular to the first direction, and a third-direction transport rail extending in a third direction, which is perpendicular to the first and second directions.

The stretching device may include a transfer film support unit for supporting the transfer film with the light-emitting elements arranged thereon and having a cylindrical shape, a fixing unit for fixing an outer circumference of the transfer film, a first mast unit for pressing the fixing unit in a third direction, and a second mast unit disposed below the first mast unit and for stretching a width of the transfer film in an outer circumferential direction by moving the first mast unit in the third direction.

The fixing unit may include a fixing frame disposed on a top surface of the outer circumference of the transfer film and a lower fixing part disposed on the second mast unit and overlapping with the fixing frame.

The transfer film support unit may include locking protrusions formed along an outer side of the cylindrical shape, and the stretching device further includes a ring-shaped stopper having locking grooves, which are coupled and fixed to the locking protrusions.

The stretching device may further include one or more third vision units disposed adjacent to the transfer film support unit and for capturing images of a distance between, and a layout of, the light-emitting elements attached to the transport head, and one or more fourth vision units disposed adjacent to the transfer film support unit and for capturing images of a location of the transfer film on the transfer film support unit, and each of the third vision units may have a higher magnification than each of the fourth vision units.

The light-emitting element transfer system may include a transfer film cassette in which a storage space for accommodating the transfer film with the light-emitting elements disposed thereon is formed, and a circuit board cassette having a storage space for accommodating the circuit board.

The light-emitting element transfer system may further include a transport module including a forklift capable of loading an object thereon, where the transport module may transport the transfer film from the transfer film cassette to the stretching device and transports the circuit board from the circuit board cassette to the circuit board support member by moving the forklift vertically and horizontally.

The light-emitting element transfer system further may include a fifth vision unit for capturing an image of at least one of a location of the circuit board on the circuit board support member, a distance between the light-emitting elements, and a layout of the light-emitting elements.

Each of the light-emitting elements may include an n-type semiconductor, an active layer, a p-type semiconductor, a first contact electrode, and a second contact electrode.

The circuit board may include flux applied to one surface thereof.

According to an embodiment, A light-emitting element transfer system includes a raw film cutting device for forming a transfer member by cutting a raw film, a reversing device for reversing the transfer member upside down and left-to-right, a stretching device for stretching a transfer film with a plurality of light-emitting elements disposed thereon, a circuit board support member for supporting a circuit board and a transport head for adsorbing the transfer member and transferring the light-emitting elements on the transfer film onto the circuit board by using the adsorbed transfer member.

According to an embodiment, A light-emitting element transfer system includes a raw film cutting device for forming a transfer member by cutting a raw film in which a base layer, a stamp layer, and a protective layer are sequentially stacked, a reversing device for reversing the transfer member upside down and left-to-right, a transport head for lifting the transfer member off from the reversing device by adsorbing the transfer member, a peeling robot configured to peel off a protective film of the transfer member adsorbed to the transport head, a stretching device for stretching a transfer film with a plurality of light-emitting elements disposed thereon and a circuit board support member supporting a circuit board, where the transport head transfers the light-emitting elements on the transfer film onto the circuit board by using the adsorbed transfer member.

According to an embodiment, A light-emitting element transfer system includes a raw film cutting device for forming a transfer member by cutting a raw film in which a base layer, a stamp layer, and a protective layer are sequentially stacked, a reversing device for reversing the transfer member upside down and left-to-right, a transport head for lifting the transfer member off from the reversing device by adsorbing the transfer member, a peeling robot configured to peel off a protective film of the transfer member adsorbed to the transport head, a stretching device for stretching a transfer film with a plurality of light-emitting elements disposed thereon, a circuit board support member for supporting a circuit board, a transfer film cassette in which a storage space for accommodating the transfer film with the light-emitting elements disposed thereon is formed, a circuit board cassette having a storage space for accommodating the circuit board and a transport module including a forklift capable of loading an object thereon, where the transport module transports the transfer film from the transfer film cassette to the stretching device and the circuit board from the circuit board cassette to the circuit board support member by moving the forklift vertically and horizontally, and the transport head transfers the light-emitting elements on the transfer film onto a circuit board by using the transfer member with the protective film peeled therefrom.

According to the aforementioned and other embodiments of the present disclosure, a transfer member can be fabricated within a system for transferring light-emitting elements, and light-emitting elements on a transfer film can be transferred onto a circuit substrate by using the transfer member.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a layout view of a display device according to an embodiment of the present disclosure;

FIG. 2 is a layout view of an exemplary pixel of FIG. 1;

FIG. 3 is a layout view of another exemplary pixel of FIG. 1;

FIG. 4 is a cross-sectional view taken along line A-A′ of FIG. 2;

FIGS. 5A and 5B are a perspective view and a plan view, respectively, of transfer equipment according to an embodiment of the present disclosure;

FIG. 6 is a block diagram of the transfer equipment of FIGS. 5A and 5B;

FIG. 7 is a schematic view of a raw film cutting device according to an embodiment of the present disclosure;

FIG. 8 is a cross-sectional view of a raw transfer member according to an embodiment of the present disclosure;

FIGS. 9 and 10 are schematic views illustrating how to obtain transfer members according to an embodiment of the present disclosure;

FIG. 11 is a cross-sectional view illustrating how the transfer members according to an embodiment of the present disclosure are disposed on a support;

FIG. 12 is a perspective view of a reversing device according to an embodiment of the present disclosure;

FIGS. 13 through 15 are side views illustrating the operation of the reversing device of FIG. 12;

FIG. 16 is a perspective view of a transport head according to an embodiment of the present disclosure;

FIG. 17 is a front view of the transport head of FIG. 16;

FIG. 18 is a plan view illustrating the movement of the transport head of FIG. 16;

FIGS. 19A and 19B are side views illustrating the movement of the transport head of FIG. 16;

FIG. 20 is a schematic view of a tape dispenser according to an embodiment of the present disclosure;

FIGS. 21, 22A, and 22B are schematic views illustrating a peeling operation of a peeling robot according to an embodiment of the present disclosure;

FIG. 23 is a schematic view illustrating the movement of the transport heads of the transfer equipment of FIGS. 5A and 5B;

FIG. 24 is a front view of a stretching device according to an embodiment of the present disclosure;

FIG. 25 is a cross-sectional view illustrating the structure of a transfer film according to an embodiment of the present disclosure;

FIG. 26 is a side view of the transfer film of FIG. 25;

FIGS. 27 through 29 are front views illustrating the operation of the stretching device of FIG. 24;

FIG. 30 is a perspective view illustrating how to transport circuit boards from a circuit board cassette with the use of a transport module according to an embodiment of the present disclosure; and

FIG. 31 is a schematic view illustrating how the transport head according to an embodiment of the present disclosure places light-emitting elements on a circuit board.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

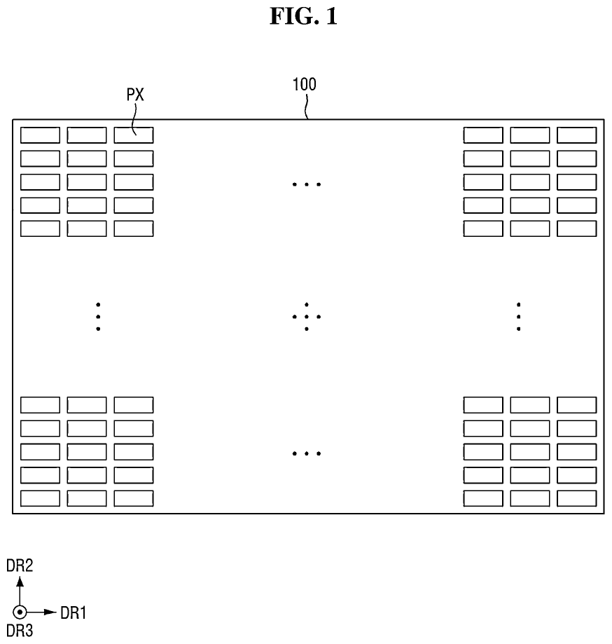

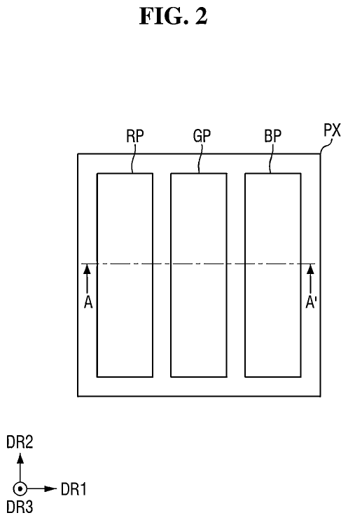

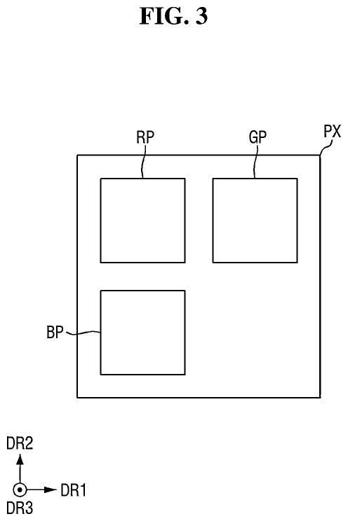

FIG. 1 is a layout view of a display device according to an embodiment of the present disclosure. FIG. 2 is a layout view of an exemplary pixel of FIG. 1. FIG. 3 is a layout view of another exemplary pixel of FIG. 1.

Referring to FIGS. 1 through 3, a display device 100, which is a device for displaying a moving or still image, may be used not only as the display screen of a portable electronic device such as a mobile phone, a smartphone, a tablet personal computer (“PC”), a smartwatch, a watchphone, a mobile communication terminal, an electronic notepad, an electronic book (e-book), a portable multimedia player (“PMP”), a navigation device, or a ultra-mobile PC (“UMPC”), but also as the display screen of various other products such as a television (“TV”), a laptop computer, a monitor, a billboard, or an Internet-of-Things (“IoT”) device.

A display device 100 may be formed into a rectangular shape having long sides in a first direction DR1 and short sides in a second direction DR2, which intersects the first direction DR1. The corners where the long sides and the short sides of the display device 100 meet may be right-angled or may be rounded to have a predetermined curvature. The planar shape of the display device 100 is not particularly limited, and the display device 100 may have various other shapes such as a non-tetragonal polygonal shape, a circular shape, or an elliptical shape. For example, the display device 100 may be formed to be flat, but the present disclosure is not limited thereto. In another example, the display device 100 may include curved parts, which are formed at opposite ends of the display device 100 and have a uniform or varying curvature. The display device 100 may be formed to be flexible such as bendable, foldable, or rollable.

The display device 100 may include pixels PX, which are for displaying an image, scan lines, which extend in the first direction DR1, and data lines, which extend in the second direction DR2. The pixels PX may be arranged in a matrix along the first and second directions DR1 and DR2.

Referring to FIGS. 2 and 3, a pixel PX may include a plurality of subpixels RP, GP, and BP. FIGS. 2 and 3 illustrate that a pixel PX includes three subpixels, i.e., first, second, and third subpixels RP, GP, and BP, but the present disclosure is not limited thereto.

The first, second, and third subpixels RP, GP, and BP may be connected to one of the data lines and at least one of the scan lines.

The first, second, and third subpixels RP, GP, and BP may have a rectangular, square, or rhombus shape in a plan view. For example, referring to FIG. 2, the first, second, and third subpixels RP, GP, and BP may have a rectangular shape having short sides in the first direction DR1 and long sides in the second direction DR2. In another example, referring to FIG. 3, the first, second, and third subpixels RP, GP, and BP may have a square or rhombus shape having four equal sides in the first and second directions DR1 and DR2.

Referring to FIG. 2, the first, second, and third subpixels RP, GP, and BP may be arranged side-by-side in the first direction DR1. Alternatively, the first subpixel RP and one of the second and third subpixels GP and BP may be arranged side-by-side in the first direction DR1, and the first subpixel RP and the other one of the second and third subpixels GP and BP may be arranged side-by-side in the second direction DR2. For example, referring to FIG. 3, the first and second subpixels RP and GP may be arranged side-by-side in the first direction DR1, and the first and third subpixels RP and BP may be arranged side-by-side in the second direction DR2.

Alternatively, the second subpixel GP and one of the first and third subpixels RP and BP may be arranged side-by-side in the first direction DR1, and the second subpixel GP and the other one of the first and third subpixels RP and BP may be arranged side-by-side in the second direction DR2. Alternatively, the third subpixel BP and one of the first and second subpixels RP and GP may be arranged side-by-side in the first direction DR1, and the third subpixel BP and the other one of the first and second subpixels RP and GP may be arranged side-by-side in the second direction DR2.

The first subpixel RP may include a first light-emitting element, which emits first light, the second subpixel GP may include a second light-emitting element, which emits second light, and the third subpixel BP may include a third light-emitting element, which emits third light. Here, the first light may be red-wavelength light, the second light may be green-wavelength light, and the third light may be blue-wavelength light. The red-wavelength light may be in the range of wavelengths of about 600 nm to about 750 nm, the green-wavelength light may be in the range of wavelengths of about 480 nm to about 560 nm, and the blue-wavelength light may be in the range of wavelengths of about 370 nm to about 460 nm. However, the present disclosure is not limited to this.

Each of the first, second, and third subpixels RP, GP and BP may include an inorganic light-emitting element having an inorganic semiconductor as a light-emitting element capable of emitting light. For example, the inorganic light-emitting element may be a flip chip-type micro-light-emitting diode (“micro-LED”), but the present disclosure is not limited thereto.

Referring to FIGS. 2 and 3, the first, second, and third subpixels RP, GP, and BP may have substantially the same area, but the present disclosure is not limited thereto. At least one of the first, second, and third subpixels RP, GP, and BP may differ from the other subpixels. Alternatively, only one of the first, second, and third subpixels RP, GP, and BP may have a different area from the other subpixels. Alternatively, the first, second, and third subpixels RP, GP, and BP may all have different areas.

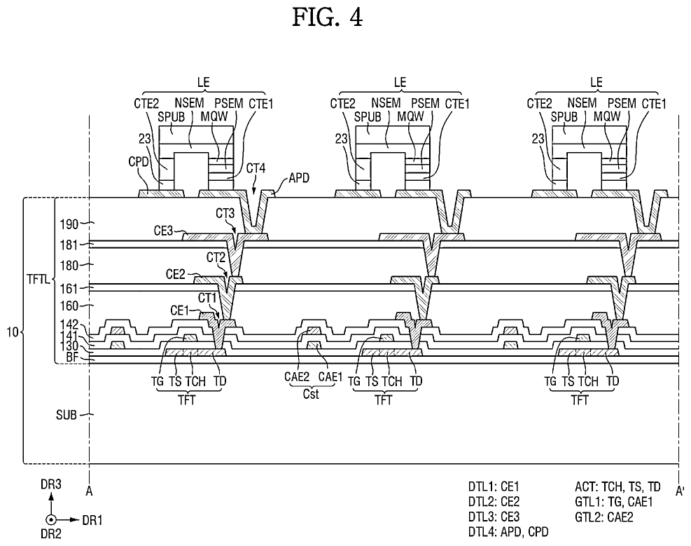

FIG. 4 is a cross-sectional view taken along line A-A′ of FIG. 2.

Referring to FIG. 4, the display device 100 may include a thin-film transistor (“TFT”) layer TFTL and light-emitting elements LE, which are disposed on a substrate SUB. The TFT layer TFTL may be a layer in which TFTs “TFT” are formed.

The TFT layer TFTL includes an active layer ACT, a first gate layer GTL1, a second gate layer GTL2, a first data metal layer DTL1, a second data metal layer DTL2, a third data metal layer DTL3, and a fourth data metal layer DTL4. The TFT layer TFTL may also include a buffer film BF, a gate insulating film 130, a first interlayer insulating film 141, a second interlayer insulating film 142, a first planarization film 160, a first insulating film 161, a second planarization film 180, and a second insulating film 181.

The substrate SUB may be a base substrate or member for supporting the display device 100. The substrate SUB may be a glass-based rigid substrate, but the present disclosure is not limited thereto. The substrate SUB may be a flexible substrate that is bendable, foldable, or rollable, in which case, the substrate SUB may include an insulating material such as a polymer resin (e.g., polyimide (“PI”)).

The buffer film BF may be disposed on one surface of the substrate SUB. The buffer film BF may be a film for preventing the permeation of the air or moisture. The buffer film BF may include a plurality of inorganic films that are alternately stacked. For example, the buffer film BF may be formed as a multilayer film in which at least one inorganic film selected from among a silicon nitride layer, a silicon oxynitride layer, a silicon oxide layer, a titanium oxide layer, and an aluminum oxide layer is alternately stacked. The buffer film BF may be optional.

The active layer ACT may be disposed on the buffer film BF. The active layer ACT may include an oxide semiconductor or a silicon semiconductor such as polycrystalline silicon, monocrystalline silicon, low-temperature polycrystalline silicon, or amorphous silicon.

The active layer ACT may include channels TCH, first electrodes TS, and second electrodes TD of the TFTs “TFT.” The channels TCH may be parts of the TFTs “TFT” that overlap with gate electrodes TG of the TFTs “TFT.” The first electrodes TS may be disposed on first sides of the channels TCH, and the second electrodes TD may be disposed on second sides of the channels TCH. The first electrodes TS and the second electrodes TD may be parts of the TFTs “TFT” that do not overlap with the gate electrodes TD in a third direction DR3. The first electrodes TS and the second electrodes TD may be conductive regions obtained by doping a silicon semiconductor or an oxide semiconductor with ions.

The gate insulating film 130 may be disposed on the active layer ACT. The gate insulating film 130 may be formed as an inorganic film such as, for example, a silicon nitride layer, a silicon oxynitride layer, a silicon oxide layer, a titanium oxide layer, or an aluminum oxide layer.

The first gate layer GTL1 may be disposed on the gate insulating film 130. The first gate layer GTL1 may include the gate electrodes TG of the TFTs “TFT” and first capacitor electrodes CAE1. The first gate layer GTL1 may be formed as a single- or multilayer film including at least one of molybdenum (Mo), aluminum (Al), chromium (Cr), gold (Au), titanium (Ti), nickel (Ni), neodymium (Nd), copper (Cu), and an alloy thereof.

The first interlayer insulating film 141 may be disposed on the first gate layer GTL1. The first interlayer insulating film 141 may be formed as an inorganic film such as, for example, a silicon nitride layer, a silicon oxynitride layer, a silicon oxide layer, a titanium oxide layer, or an aluminum oxide layer.

The second gate layer GTL2 may be disposed on the first interlayer insulating film 141. The second gate layer GTL2 may include second capacitor electrodes CAE2. The second gate layer GTL2 may be formed as a single- or multilayer film including at least one of Mo, Al, Cr, Au, Ti, Ni, Nd, Cu, and an alloy thereof.

The second interlayer insulating film 142 may be disposed on the second gate layer GTL2. The second interlayer insulating film 142 may be formed as an inorganic film such as, for example, a silicon nitride layer, a silicon oxynitride layer, a silicon oxide layer, a titanium oxide layer, or an aluminum oxide layer.

The first data metal layer DTL1, which includes first connecting electrodes CE1, first sub-pads SPD1, and data lines DL, may be disposed on the second interlayer insulating film 142. The data lines DL may be integrally formed with the first sub-pads SPD1, but the present disclosure is not limited thereto. The first data metal layer DTL1 may be formed as a single- or multilayer film including at least one of Mo, Al, Cr, Au, Ti, Ni, Nd, Cu, and an alloy thereof.

The first connecting electrodes CE1 may be connected to the first electrodes TS or the second electrodes TD of the TFTs “TFT” through first contact holes CT1, which penetrate the first and second interlayer insulating films 141 and 142.

The first planarization film 160, which is for planarizing step differences formed by the active layer ACT, the first gate layer GTL1, the second gate layer GTL2, and the first data metal layer DTL1, may be disposed on the first data metal layer DTL1. The first planarization film 160 may be formed as an organic film including an acrylic resin, an epoxy resin, a phenolic resin, a polyamide resin, or a polyimide resin.

The second data metal layer DTL2 may be disposed on the first planarization film 160. The second data metal layer DTL2 may include the second connecting electrodes CE2 and second sub-pads PD2. The second connecting electrodes CE2 may be connected to the first connecting electrodes CE1 through second contact holes CT2, which penetrate the first insulating film 161 and the first planarization film 160. The second data metal layer DTL2 may be formed as a single- or multilayer film including at least one of Mo, Al, Cr, Au, Ti, Ni, Nd, Cu, and an alloy thereof.

The second planarization film 180 may be disposed on the second data metal layer DTL2. The second planarization film 180 may be formed as an organic film including an acrylic resin, an epoxy resin, a phenolic resin, a polyamide resin, or a polyimide resin.

The third data metal layer DTL3 may be disposed on the second planarization film 180. The third data metal layer DTL3 may include third connecting electrodes CE3 and third sub-pads SPD3. The third connecting electrodes CE3 may be connected to the second connecting electrodes CE2 through third contact holes CT3, which penetrate the second insulating film 181 and the second planarization film 180. The third data metal layer DTL3 may be formed as a single- or multilayer film including at least one of Mo, Al, Cr, Au, Ti, Ni, Nd, Cu, and an alloy thereof.

The third planarization film 190 may be disposed on the third data metal layer DTL3. The third planarization film 190 may be formed as an organic film including an acrylic resin, an epoxy resin, a phenolic resin, a polyamide resin, or a polyimide resin.

The fourth data metal layer DTL4 may be disposed on the third planarization film 190. The fourth data metal layer DTL4 may include anode pad electrodes APD, cathode pad electrodes CPD, and fourth sub-pads SPD. The anode pad electrodes APD may be connected to the third connecting electrodes CE3 through fourth contact holes CT4, which penetrate the third insulating film 191 and the third planarization film 190. The cathode pad electrodes CPD may receive a first power supply voltage, which is a low-potential voltage. The fourth data metal layer DTL4 may be formed as a single- or multilayer film including at least one of Mo, Al, Cr, Au, Ti, Ni, Nd, Cu, and an alloy thereof.

The light-emitting elements LE are illustrated as being flip chip-type micro-LEDs in which the first contact electrodes CTE1 and the second contact electrodes CTE2 face the anode pad electrodes APD and the cathode pad electrodes CPD, but the present disclosure is not limited thereto. The light-emitting elements LE may be inorganic light-emitting elements formed of an inorganic material such as GaN. The light-emitting elements LE may have a length of several to hundreds of micrometers in the first, second, and third directions DR1, DR2, and DR3. For example, the light-emitting elements LE may have a length of 100 μm in the first, second, and third directions DR1, DR2, and DR3.

The light-emitting elements LE may be grown from a semiconductor substrate such as a silicon wafer. The light-emitting elements LE may be transferred from the silicon wafer onto the anode pad electrodes APD and the cathode pad electrodes CPD on the substrate SUB. In this case, the first contact electrodes CTE1 and the anode pad electrodes APD may be bonded together by a bonding process. The second contact electrodes CTE2 and the cathode pad electrodes CPD may also be bonded together by a bonding process. The first contact electrodes CTE1 and the anode pad electrodes APD may be electrically connected through bonding electrodes 23. The second contact electrodes CTE2 and the cathode pad electrodes CPD may be electrically connected through the bonding electrodes 23.

For example, the bonding electrodes 23 may be disposed on surfaces of the light-emitting elements LE. The bonding electrodes 23 may be the products of a pressure melting process using laser. Here, the pressure melting process is a process in which the bonding electrodes 23 are melted by heat so that the light-emitting elements LE, the anode pad electrodes APD, and the cathode pad electrodes CPD are melted and fused together, and then cool and solidify when the supply of laser light is terminated. As the conductivity of the light-emitting elements LE, the anode pad electrodes APD, and the cathode pad electrodes CPD is maintained while the light-emitting elements LE, the anode pad electrodes APD, and the cathode pad electrodes CPD are cooling and solidifying from a molten state, the light-emitting elements LE, the anode pad electrodes APD, and the cathode pad electrodes CPD can be electrically and physically connected together. Accordingly, the bonding electrodes 23 may be disposed on the first contact electrodes CTE1 and the second contact electrodes CTE2 of the light-emitting elements LE.

The bonding electrodes 23 may include, for example, Au, AuSn, PdIn, InSn, NiSn, Au—Au, AgIn, AgSn, Al, Ag, or carbon nanotube (“CNT”), and these materials may be used alone or in combination of one another.

The light-emitting elements LE may be light-emitting structures including base substrates SUB, n-type semiconductors NSEM, active layers MQW, p-type semiconductors PSEM, the first contact electrodes CTE1, and the second contact electrodes CTE2.

The base substrate SSUB may be a sapphire substrate, but the present disclosure is not limited thereto.

The n-type semiconductors NSEM may be disposed on the base substrates SSUB. For example, the n-type semiconductors NSEM may be disposed on the bottom surfaces of the base substrates SSUB. The n-type semiconductors NSEM may be formed of GaN doped with an n-type conductivity dopant such as Si, Ge, or Sn.

The active layers MQW may be disposed on parts of the n-type semiconductors NSEM. The active layers MQW may include a material with a single- or multi-quantum well structure. In a case where the active layers MQW include a material with a multi-quantum well structure, the active layers MQW may have a structure in which a plurality of well layers and barrier layers are alternately stacked. Here, the well layers may be formed of InGaN, and the barrier layers may be formed of GaN or AlGaN. However, the present disclosure is not limited to this. Alternatively, the active layers MQW may have a structure in which semiconductor materials with a large bandgap energy and semiconductor materials with a small bandgap energy are alternately stacked or may include group-III to group-IV semiconductor materials depending on the range of wavelengths to be emitted.

Flip chip-type light-emitting elements have been described as exemplary light-emitting elements LE, but the present disclosure is not limited thereto. Alternatively, the light-emitting elements LE may be vertical light-emitting elements.

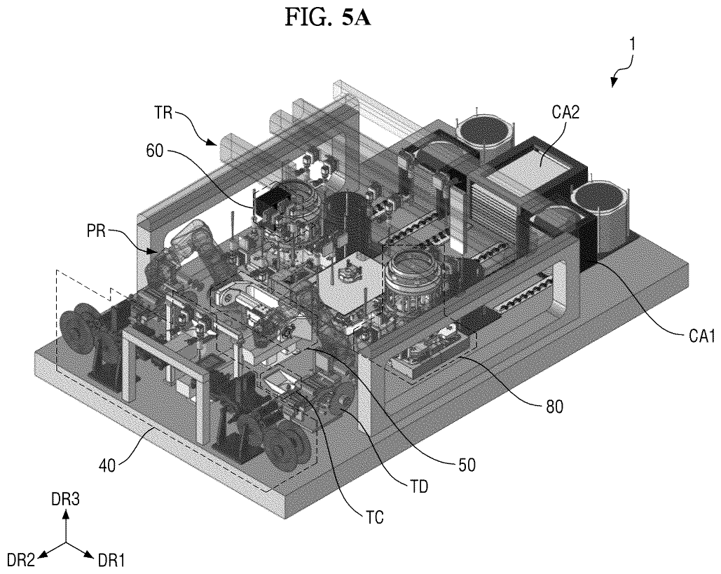

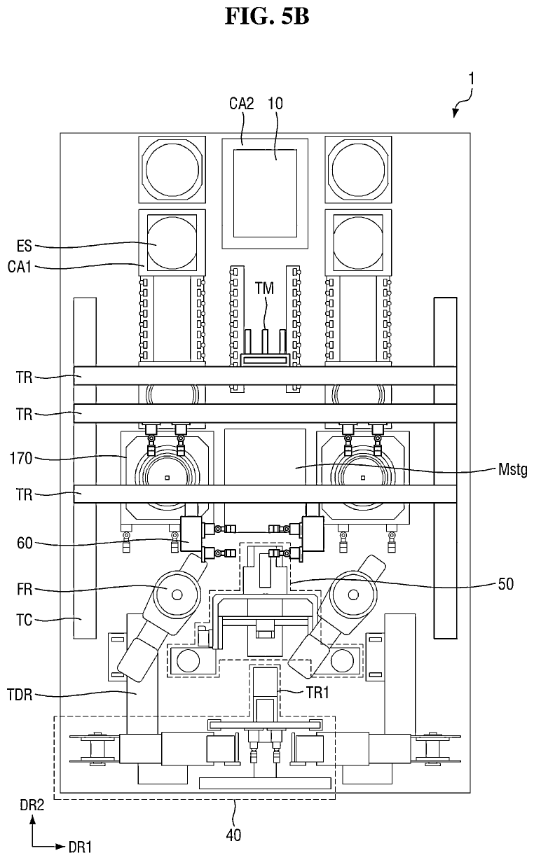

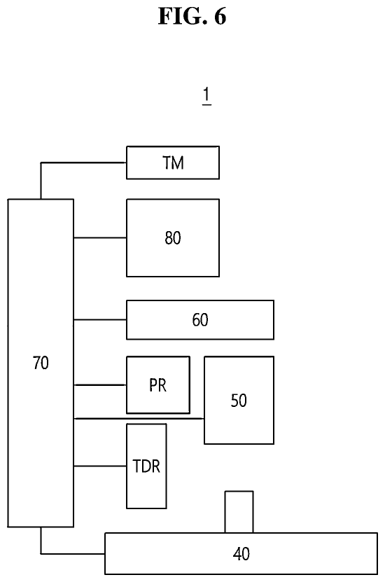

FIGS. 5A and 5B are a perspective view and a plan view, respectively, of transfer equipment according to an embodiment of the present disclosure, and FIG. 6 is a block diagram of the transfer equipment of FIGS. 5A and 5B.

Referring to FIGS. 5A, 5B, and 6, transfer equipment 1 for transferring light-emitting elements according to an embodiment of the present disclosure may fabricate a transfer member and may transfer light-emitting elements on a circuit film onto a circuit substrate by using the transfer member.

Specifically, the transfer equipment 1 includes a raw film cutting device 40, reversing devices 50, transport heads 60, stretching devices 80, and a control device 70. The transfer equipment 1 may further include peeling robots PR, a tape dispenser TDR, collection bins TC, transport rails TR, a transport module TM, a circuit board support member Mstg, transfer film cassettes CA1, and a circuit board cassette CA2.

Referring to FIGS. 5A and 5B, two reversing devices 50, two transport heads 60, two stretching devices 80, two peeling robots PR, and two collection bins TC are provided symmetrically, but the numbers of reversing devices 50, transport heads 60, stretching devices 80, peeling robots PR, and collection bins TC are not particularly limited.

Referring again to FIGS. 5A, 5B, and 6, the raw film cutting device 40 (or the cutting device 40) forms transfer members by cutting a raw film.

The reversing devices 50 reverse the transfer members.

The circuit board support member Mstg supports a circuit board 10.

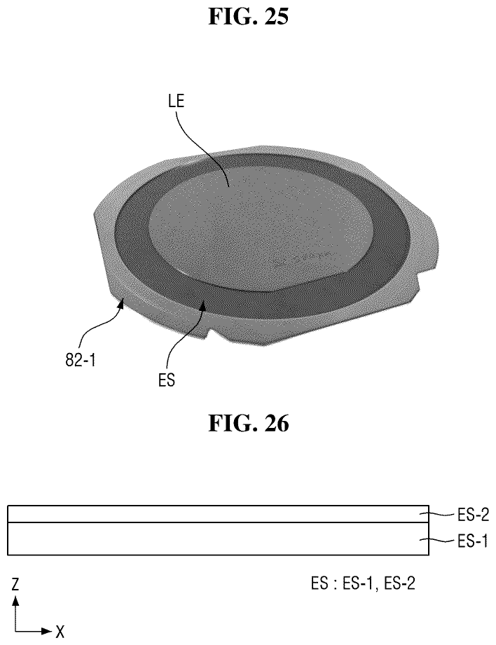

The transport heads 60 adsorb the transfer members and transfer light-emitting elements (“LE” of FIG. 25), which are disposed on a transfer film ES, onto the circuit board 10, which is disposed on the circuit board support member Mstg.

The transport rails TR are disposed on the top or bottom surface of the transfer equipment 1 to move some of the components of the transfer equipment 1. A plurality of transport rails TR may be provided and may be arranged to extend first, second, and third directions DR1, DR2, and DR3. For example, the transport heads 60 may be movable in the first, second, and third directions DR1, DR2, and DR3 along the transport rails TR.

The transfer film cassette CA1 may be disposed adjacent to the stretching devices 80.

The transfer film cassette CA1 may include a plurality of supports and a plurality of slots, which protrude from the supports. The slots may be positioned to be opposite to face one another. The slots may support the transfer film ES and may provide space in which the transfer film ES is loaded.

The circuit board cassette CA2 may be disposed adjacent to the circuit board support member Mstg.

The circuit board cassette CA2 may include a plurality of supports and a plurality of slots, which protrude from the supports. The slots of the circuit board cassette CA2 may be positioned to be opposite to face one another. The slots of the circuit board cassette CA2 may support the circuit board 10 and may provide space in which the circuit board 10 is loaded.

The transport module TM may include a forklift capable of loading an object thereon and may move the forklift up and down and back and forth. The transport module TM transports the transfer film ES or the circuit board 10 by using the forklift. For example, the transport module TM loads the transfer film ES loaded in the transfer film cassette CA1 onto the top of the forklift and transports the transfer film ES to the stretching devices 80. The transport module TM transports the circuit board 10 loaded in the circuit board cassette CA2 to the circuit board support member Mstg.

The transfer film ES may be provided to the stretching device 80.

The stretching devices 80 stretch the transfer film ES. When the transfer film ES is stretched, the distance between the light-emitting elements LE on the transfer film ES increases.

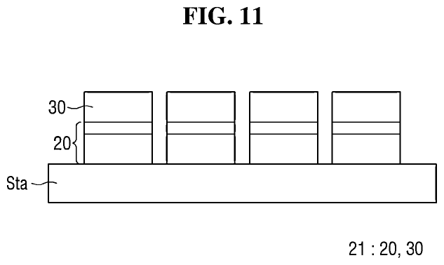

Surfaces of the transfer members are formed of an adhesive or sticky material. Target objects to be transferred, i.e., the light-emitting elements LE, may be bonded to the adhesive or sticky surfaces of the transfer members. To prevent contamination of the adhesive or sticky surfaces of the transfer members before the bonding of the light-emitting elements LE, protective films (“30” of FIG. 11) may be attached to the adhesive or sticky surfaces of the transfer members.

The peeling robots PR peel off the protective films 30 of the transfer members 21.

The peeling robots PR may use adhesive tapes to peel the protective films 30 off of the transfer members.

The tape dispenser TDR may provide the adhesive tapes to the peeling robots PR.

The peeling robots PR may peel off the protective film 30 by using the adhesive tapes and discard the adhesive tapes with the peeled-off protective films 30 attached thereto into the collection bins TC.

The control device 70 may control the operations of the other components of the transfer equipment 1, i.e., the operations of the cutting device 40, the reversing devices 50, the transport heads 60, the stretching devices 80, the peeling robots PR, and the transport module TM.

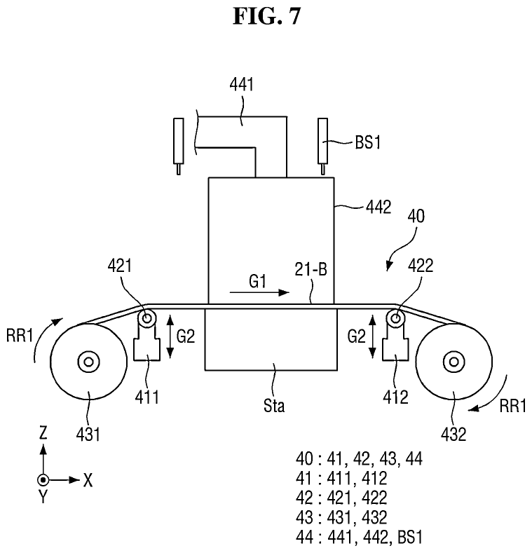

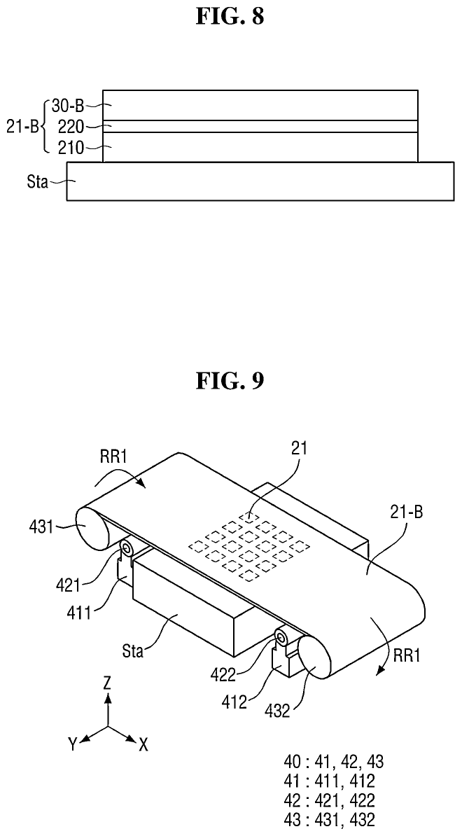

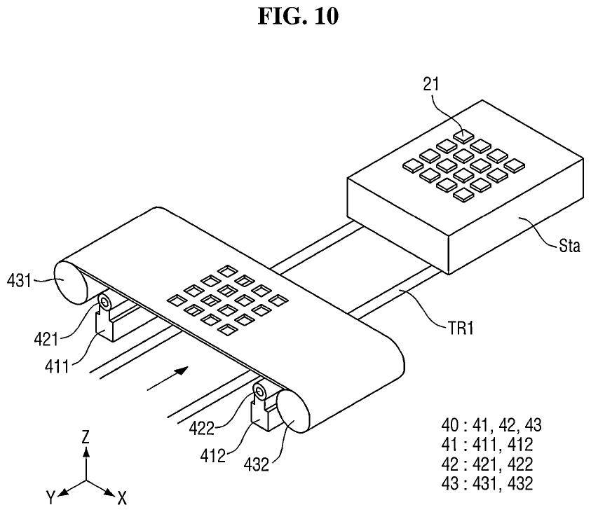

FIG. 7 is a schematic view of a raw film cutting device according to an embodiment of the present disclosure, FIG. 8 is a schematic view of a raw transfer member according to an embodiment of the present disclosure, FIGS. 9 and 10 are schematic views illustrating how to obtain transfer member according to an embodiment of the present disclosure, and FIG. 11 is a cross-sectional view illustrating how the transfer members according to an embodiment of the present disclosure are disposed on a support.

Referring to FIG. 7, the raw film cutting device 40 includes a pedestal Sta, a raw film transport unit 41, 42, and 43, and a cutting unit 44. The raw film cutting device 40 may further include one or more first vision units BS1.

The pedestal Sta supports a raw film 21-B or transfer members 21 in the raw film cutting device 40.

The raw film transport unit 41, 42, and 43 may be disposed on opposite sides of the pedestal Sta. For example, the raw film transport unit 41, 42, and 43 may be disposed on opposite sides of the raw film 21-B, which extends in a first direction X. The raw film transport unit 41, 42, and 43 transports the raw film 21-B. For example, the raw film transport unit 41, 42, and 43 may be implemented in a reel-to-reel manner that transports the raw film 21-B while unreeling the raw film 21-B, which is wound into a roll. Accordingly, the raw film transport unit 41, 42, and 43 may remove the remainder of the raw film 21-B from the cutting of the transfer members 21 out of the raw film 21-B and may place a new raw film 21-B on the pedestal Sta.

The raw film transport unit 41, 42, and 43 includes a moving unit 41, guide rollers 42, and a rolling unit 43.

The rolling unit 43 may be connected to the raw film 21-B. For example, first and second rolling parts 431 and 432 may be connected to the raw film 21-B. The rolling unit 43 may wind or unwound the raw film 21-B. For example, the first and second rolling parts 431 and 432 may rotate in the same direction to remove the remainder of the raw film 21-B from the cutting of the transfer members 21 by the cutting unit 44, and may thus place a new raw film 21-B on the pedestal Sta.

Referring to FIG. 8, the raw film 21-B may include a raw transfer member 20-B and a raw protective film 30-B.

The raw transfer member 20-B includes a base layer 210 and a stamp layer 220.

The base layer 210 may include, for example, glass or plastic. In a case where the base layer 210 includes glass, the glass may be ultrathin glass. Alternatively, the base layer 210 may be formed of polyethylene terephthalate (“PET”), polyurethane (“PU”), polyimide (“PI”), polycarbonate (“PC”), polyethylene (“PE”), polypropylene (“PP”), polysulfone (“PSF”), polymethyl methacrylate (“PMMA”), triacetyl cellulose (“TAC”), or cycloolefin polymer (“COP”).

The stamp layer 220 is disposed on one surface of the base layer 210. The stamp layer 220 may be adhered or bonded to light-emitting elements LE. The stamp layer 220 may be formed of an adhesive material such as, for example, an optically clear adhesive (“OCA”) or a pressure sensitive adhesive (“PSA”), but the present disclosure is not limited thereto. Alternatively, the stamp layer 220 may be formed of a sticky material such as, for example, an acrylic, urethane-based, or silicon-based sticky material.

The raw protective film 30-B is attached to one surface of the stamp layer 220, and the base layer 210 is attached to the other surface of the stamp layer 220.

The stamp layer 220 is attached to one surface of the base layer 210, and the other surface of the base layer 210 is exposed.

The raw protective film 30-B may be formed of a transparent material. The raw protective film 30-B may include, for example, glass or plastic. In a case where the raw protective film 30-B includes thin glass, the glass may be ultrathin glass.

The base layer 210, the stamp layer 220, and the raw protective film 30-B are sequentially disposed on a pedestal Sta.

Referring again to FIG. 7, the guide rollers 42 may support the raw film 21-B. The first guide roller 421 may support the left part of the raw film 21-B, and the second guide roller 422 may support the right part of the raw film 21-B. As the first and second guide rollers 421 and 422 support opposite sides of the raw film 21-B, the raw film 21-B can be properly placed horizontally.

Also, the guide rollers 42 may support the raw film 21-B such that the raw film 21-B may move in one direction. For example, in a case where the raw film 21-B is implemented in the reel-to-reel manner, the guide rollers 42 may support a new raw film 21-B to be transported in the first direction X via the rolling unit 43.

The moving unit 41 may move the raw film 21-B in one direction. For example, the moving unit 41 may move in a third direction Z to separate the transfer members 21 cut out of the raw film 21-B from the rest of the raw film 21-B. A first moving part 411 and the second guide roller 422 may be connected to each other. Accordingly, the raw film 21-B supported by the first and second guide rollers 421 and 422 may be movable in the third direction Z. The operation of the raw film transport unit 41, 42, and 43 will be described later with reference to FIGS. 9 and 10.

The cutting unit 44 may include a support (“440” of FIG. 7), a cutter 441, a particle suction unit 442, and the first vision units BS1.

The support 440 is disposed adjacent to the pedestal Sta.

The support 440 supports the cutter 441, the particle suction unit 442, and the first vision units BS1.

The cutter 441, which cuts the raw film 21-B into a plurality of transfer members 21, may be implemented as a typical cutter, a rotary blade, or a laser.

The particle suction unit 442 may remove particles that may be generated during the cutting of the raw film 21-B by the cutter 441. For example, the particle suction unit 442 may adsorb the particles and release the adsorbed particles out of the pedestal Sta. In another example, the particle suction unit 442 may remove the particles by spraying a high-pressure inert gas. The particle suction unit 442 may be disposed to overlap with the four side surfaces of the pedestal Sta.

In short, as illustrated in FIG. 11, the raw film 21-B transported onto the pedestal Sta by the raw film transport unit 41, 42, and 43 may be cut into a plurality of transfer members 21 by the cutting unit 44, and particles generated from the cutting of the raw film 21-B may be removed by the particle suction unit 442.

Each of the first vision units BS1 may include one or more cameras.

The transfer members 21 cut by the cutter 441 may be the subjects of each of the first vision units BS1.

The first vision units BS1 may capture images of the raw film 21-B and the transfer members 21 on the pedestal Sta. For example, the first vision units BS1 capture images of the transfer members 21 or generates image data regarding the transfer members 21, and transmits the image or the image data to a control device (“70” of FIG. 6). The control device 70 may determine whether the transfer members 21 are defective based on how the transfer members 21 are cut, by using the images or the image data provided by the first vision units BS1.

For example, referring to FIGS. 7, 9, and 10, if the first and second moving parts 411 and 412 move in one direction (e.g., in an upward direction) in the third direction Z after the cutting of the transfer members 21 out of the raw film 21-B, the first guide roller 421, which is connected to the first moving part 411, may move in the third direction Z, and as a result, the raw film 21-B supported by the first guide roller 421 may also move in the third direction Z. The second guide roller 422, which is connected to the second moving part 412, may move in the third direction Z, and as a result, the raw film 21-B supported by the first guide roller 421 may also move in the third direction Z.

In short, as the moving unit 41 moves in the third direction Z (e.g., in the upward direction) or in the opposite direction of the third direction Z (e.g., in a downward direction), the raw film 21-B may also move in the third direction Z (e.g., in the upward direction) or in the opposite direction of the third direction Z (e.g., in the downward direction). The raw film 21-B may move in the opposite direction of the third direction Z to be placed in contact with the surface of the pedestal Sta or may move in the third direction Z to be detached from the pedestal Sta.

A first transport rail TR1 is disposed under the pedestal Sta and the raw film cutting device 40. When the raw film 21-B moves in the third direction Z and is thus detached from the pedestal Sta, the pedestal Sta slidably moves along the first transport rail TR1.

A first rolling part 431 may rotate in a first rotational direction RR1. For example, when the moving unit 41 moves in the third direction Z (e.g., in the upward direction) to above the raw film 21-B, the first rolling part 431 may rotate in the first rotational direction RR1. Accordingly, the raw film 21-B connected to the first rolling part 431 may be unwound from the first rolling part 431. Therefore, when the first rolling part 431 rotates in the first rotational direction RR1, the amount of the raw film 21-B wound around the first rolling part 431 decreases.

The second rolling part 432 may also rotate in the first rotational direction RR1. For example, when the moving unit 41 moves in the third direction Z (e.g., in the upward direction) to above the raw film 21-B, the second rolling part 432 may rotate in the first rotational direction RR1. Accordingly, the raw film 21-B connected to the second rolling part 432 may be wound around the second rolling part 432.

Thus, as the first and second rolling parts 431 and 432 rotate in the first rotational direction RR1, the raw film 21-B may be transported in a first driving direction G1. That is, the remainder of the raw film 21-B after the cutting of the transfer members 21 may be transported to the second rolling part 432, and a new raw film 21-B may be transported from the first rolling part 431 to the pedestal Sta.

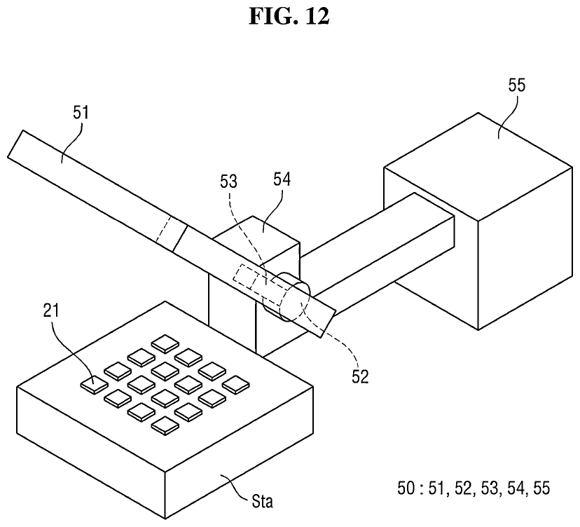

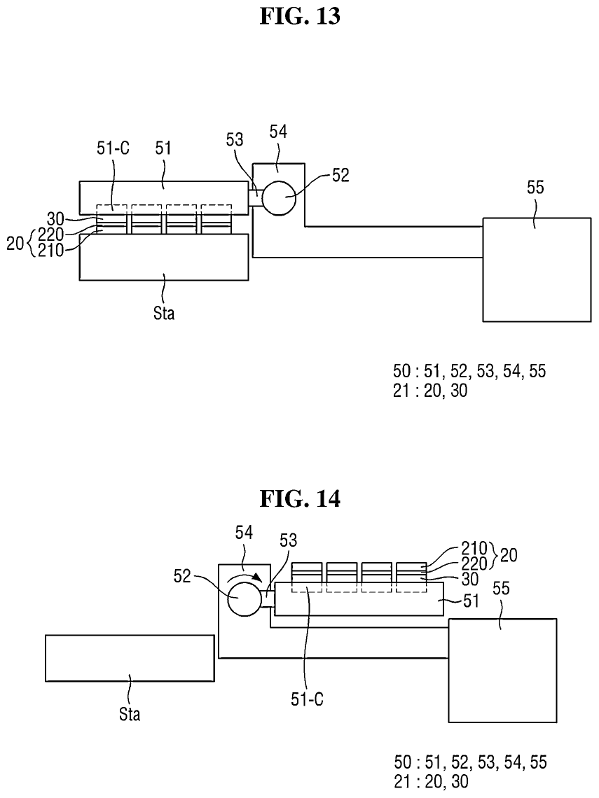

FIG. 12 is a perspective view of a reversing device according to an embodiment of the present disclosure, and FIGS. 13 through 15 are side views illustrating the operation of the reversing device of FIG. 12.

Referring to FIGS. 12 through 15, a reversing device 50 reverses a plurality of transfer members 21 180 degrees.

The reversing device 50 may include a stage 51, a rotational shaft 52, a first connector 53, which connects the stage 51 and the rotational shaft 52, a vertical driver 55, and a second connector 54, which connects the rotational shaft 52 and the vertical driver 55.

The stage 51 may include a plurality of support chucks 51-c. Each of the support chucks 51-c may be any one of an electrostatic chuck, an adhesive chuck, a vacuum chuck, and a porous vacuum chuck. The support chucks 51-c may adsorb and thereby fix the surfaces of the transfer members 21 on the pedestal Sta.

When the support chucks 51-c adsorb the transfer members 21, the stage 51 may rotate 180 degrees about the rotational shaft 52. The transfer members 21 are turned upside down by the rotation of the stage 51. Accordingly, protective films 30, stamp layers 220, and base layers 230 of the transfer members 21 are sequentially disposed on the stage 51.

The second connector 54 is formed in an “L” shape. The rotational shaft 52 is rotatably connected to one end of the rotational shaft 52, and the vertical driver 55 is connected to the other end of the rotational shaft 52.

The vertical driver 55 may move the second connector 54 in the third direction Z (e.g., in the upward direction) and in the opposite direction of the third direction Z (e.g., in the downward direction). When the vertical driver 55 moves the second connector 54 in the third direction Z (e.g., in the upward direction), the rotational shaft 52, which is connected to the second connector 54, the first connector 53, which is connected to the rotational shaft 52, and the stage 51, which is connected to the first connector 53, move in the third direction Z (e.g., in the upward direction).

Also, when the vertical driver 55 moves the second connector 54 in the opposite direction of the third direction Z (e.g., in the downward direction), the rotational shaft 52, which is connected to the second connector 54, the first connector 53, which is connected to the rotational shaft 52, and the stage 51, which is connected to the first connector 53, move in the opposite direction of the third direction Z (e.g., in the downward direction).

The vertical driver 55 may be driven by a pneumatic or hydraulic pressure control method. For example, the vertical driver 55 may include a hydraulic cylinder 55-1 and a hydraulic pump 55-2, which is connected to the hydraulic cylinder 55-1. The hydraulic pump 55-2 may provide a driving force to the vertical driver 55 through the hydraulic cylinder 55-1. An additional member 55-3 may be further included for changing the direction of the driving force in accordance with the positions of the hydraulic cylinder 55-1 and the hydraulic pump 55-2. The hydraulic cylinder 55-1 and the hydraulic pump 55-2 are merely exemplary, and the present disclosure is not limited thereto. That is, various well-known methods may be used to vertically move the vertical driver 55.

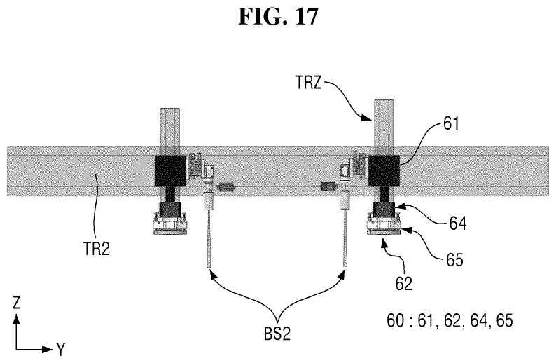

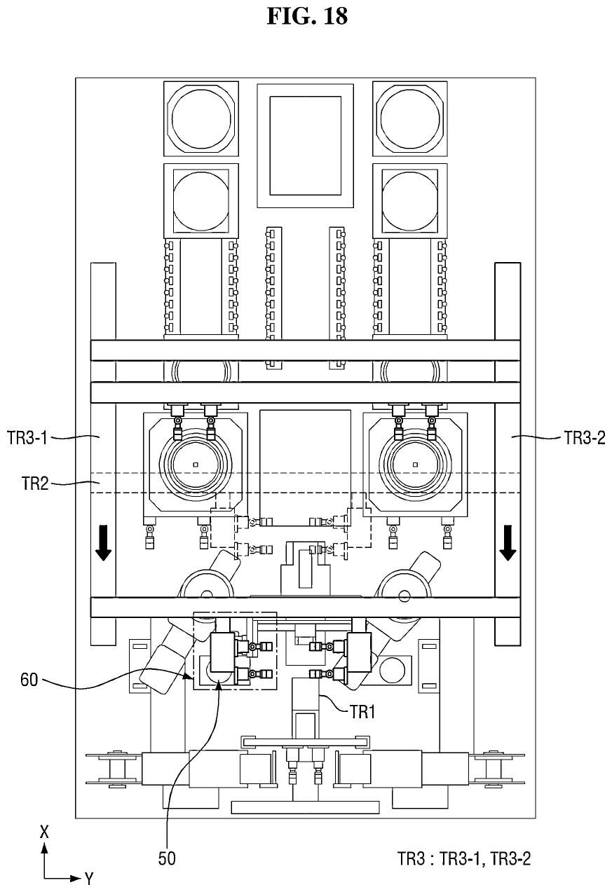

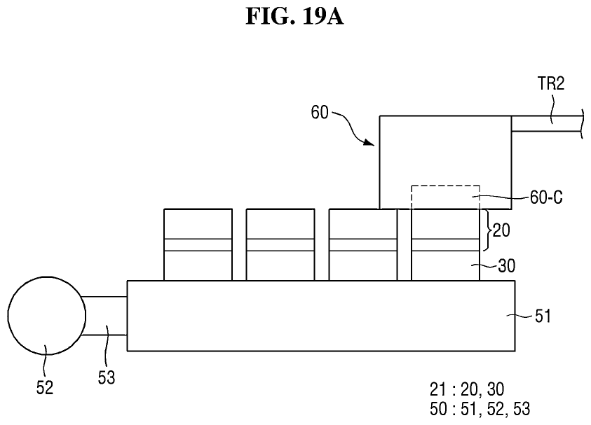

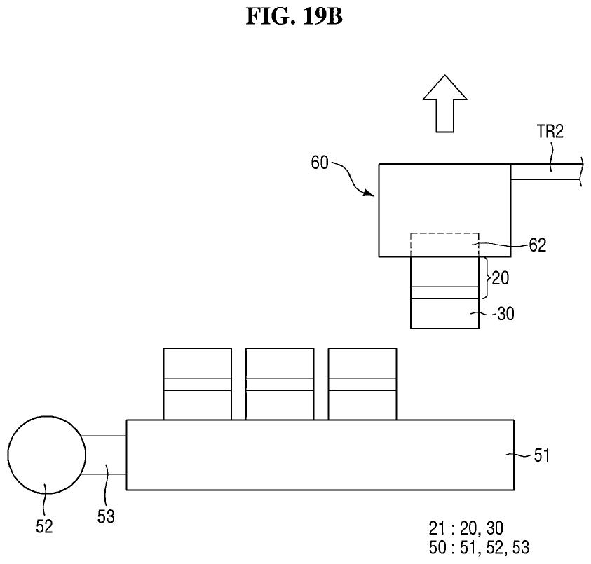

FIG. 16 is a perspective view of a transport head according to an embodiment of the present disclosure. FIG. 17 is a front view of the transport head of FIG. 16. FIG. 18 is a plan view illustrating the movement of the transport head of FIG. 16. FIGS. 19A and 19B are side views illustrating the movement of the transport head of FIG. 16.

Referring to FIGS. 16 through 19B, a transport head 60 may include a body part 61, a head chuck 62, a rotation driver 64, a tilt driver 65, and one or more second vision units BS2.

The head chuck 62 may be any one of an electrostatic chuck, an adhesive chuck, a vacuum chuck, and a porous vacuum chuck. That is, the head chuck 62 may adsorb and fix the transfer member 21 in an electrostatic adsorption method, a vacuum adsorption method, or the like.

The head chuck 62 is connected to the body part 61 through the rotation driver 64 and the tilt driver 65.

The rotation driver 64 may rotate the head chuck 62, and the tilt driver 65 may tilt the head chuck 62 on a horizontal plane.

The body part 61, which is the body of the transport head 60, may move the head chuck 62 in the third direction Z along a head transport rail TRZ.

The second vision units BS2 may be disposed on one surface of the body part 61 or on the head transport rail TRZ. In a case where the second vision units BS2 are disposed on the head transport rail TRZ, the second vision units BS2 may be movable along the head transport rail TRZ.

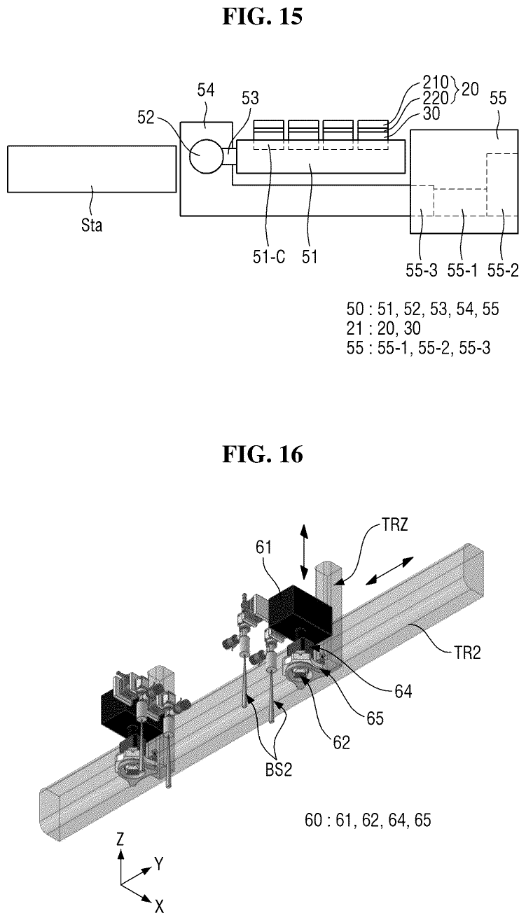

Each of the second vision units BS2 may include one or more cameras and may generate data by capturing an image of an object below the transport head 60. For example, the second vision units BS2 capture images of the transfer members 21 on a reversing device (“50” of FIG. 15). The second vision units BS2 transmit the generated data to a control device (“70” of FIG. 6). The control device 70 may determine whether the transfer members 21 are aligned with the head chuck 62 based on the data transmitted by the second vision units BS2. The control device 70 may control the position of the head chuck 62 based on the data transmitted by the second vision units BS2. For example, the control device 70 may control the position of the body part 61 based on the data transmitted by the second vision units BS2 such that the transfer members 21 and the head chuck 62 may be aligned with one another.

Referring to FIG. 18, the body part 61 may move in the first and second directions X and Y along a second transport rail TR2, which extends in the second direction Y, and a pair of third transport rails TR3, which extend in the first direction X.

The head transport rail TRZ may be disposed on one side of the second transport rail TR2 and may be slidable in the second direction Y along the second transport rail TR2.

The third transport rails TR3 may be disposed at opposite ends of the second transport rail TR2. For example, the third transport rails TR3 may include right and left third transport rails TR3-1 and TR3-2, and the right and left third transport rails TR3-1 and TR3-2 may be disposed at opposite ends of the second transport rail TR2.

The second transport rail TR2 may be slidable in the first direction X or in the opposite direction of the first direction X along the third transport rails TR3.

Referring to FIGS. 18, 19A, and 19B, when the second transport rail TR2 slides in the first direction X (e.g., in a forward direction) along the third transport rails TR3, the head chuck 62 of the transport head 60 is disposed to overlap with a stage 51 of a reversing device 50.

When the transport head 60 is disposed to overlap with the stage 51 of the reversing device 50, the transport head 60 may be slidable in the opposite direction of the third direction Z along the head transport rail TRZ.

When the transport head 60 slides in the opposite direction of the third direction Z (e.g., in the downward direction), the head chuck 62 of the transport head 60 may be in contact with the surfaces of the transfer members 21 on the stage 51.

When the head chuck 62 is in contact with the surfaces of the transfer members 21 on the stage 51, the head chuck 62 may adsorb and fix the surfaces of the transfer members 21. Also, when the head chuck 62 adsorbs and fixes the surfaces of the transfer members 21, the transport head 60 slides in the third direction Z (e.g., in the upward direction) to separate the transfer members 21 from the reversing device 50.

Thereafter, the reversing device 50 may move in the first direction X (e.g., in the forward direction) along a first transport rail (“TR1” of FIG. 10) and may return to its original location.

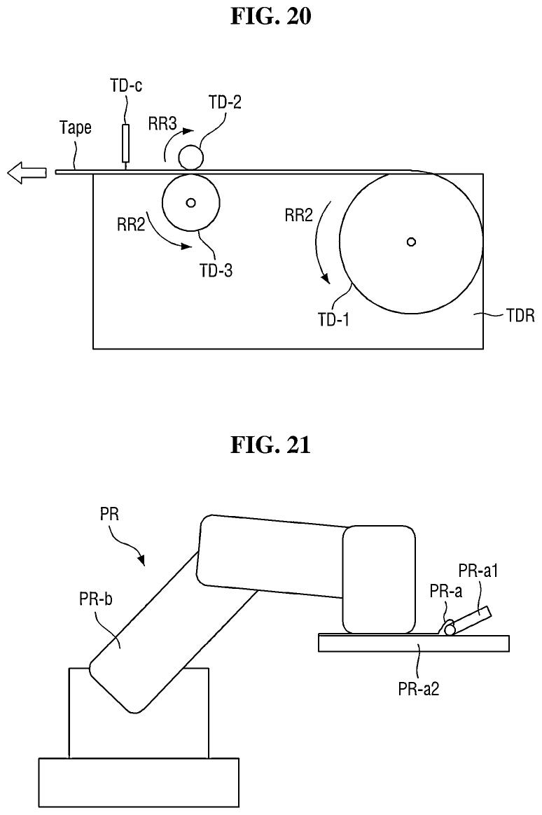

FIG. 20 is a schematic view of a tape dispenser according to an embodiment of the present disclosure.

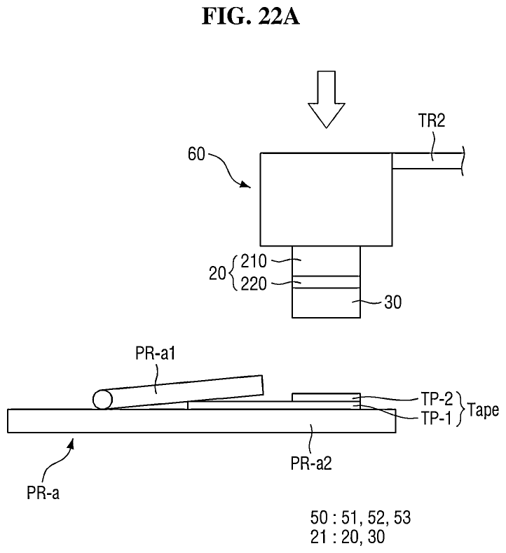

Referring to FIG. 20, a tape dispenser TDR provides a tape to a peeling robot (“PR” of FIG. 21).

The tape dispenser TDR may include a winding roller TD-1, an upper pressure roller TD-2, a lower pressure roller TD-3, and a cutting part TD-c.

The winding roller TD-1 may include a tape roll on which a tape is wound and may rotate in a second rotational direction RR2. Accordingly, the tape roll wound around the winding roller TD-1 may be released from the winding roller TD-1. Therefore, when the winding roller TD-1 rotates in the second rotational direction RR2, the amount of the tape roll wound around the winding roller TD-1 decreases.

The upper pressure roller TD-2 and the lower pressure roller TD-3 are disposed in a direction in which the tape is unwound from the winding roller TD-1 and are positioned above and below, respectively, the tape. The lower pressure roller TD-3 rotates in the second rotational direction RR2, which is the same as the rotational direction of the winding roller TD-1, and the upper pressure roller TD-2 rotates in the opposite direction of the rotational direction of the winding roller TD-1, i.e., in the opposite direction of the second rotational direction RR2. Thus, the upper pressure roller TD-2 and the lower pressure roller TD-3 help the tape unwound from the winding roller TD-1 to continue to travel in the direction in which the tape is unwound from the winding roller TD-1. Also, the upper pressure roller TD-2 and the lower pressure roller TD-3 pressurize the tape unwound from the winding roller TD-1 not to return back to the winding roller TD-1.

The cutting part TD-c is disposed in the direction in which the tape is unwound from the winding roller TD-1, farther than the upper pressure roller TD-2 and the lower pressure roller TD-3, and cuts the tape. The cutting part TD-c may include a cutting bracket and a cutter blade. The cutting bracket is a device that provides space where the cutter blade can be coupled. The cutter blade is provided on one side of the cutting bracket. The cutter blade may be already well known in the art, to which the present disclosure pertains, and thus, a detailed description thereof will be omitted. The tape exiting the upper pressure roller TD-2 and the lower pressure roller TD-3 is cut by the cutting part TD-c.

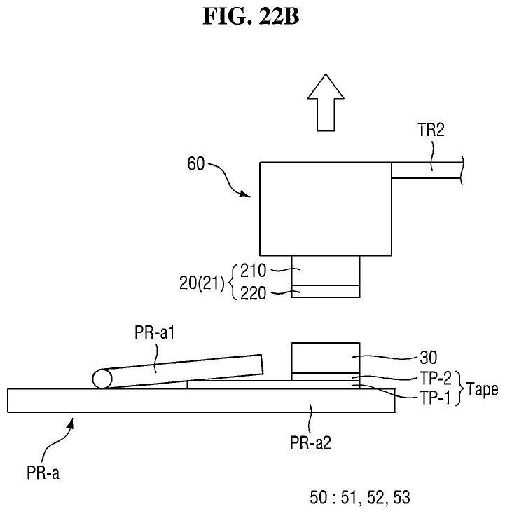

FIGS. 21, 22A, and 22B are schematic views illustrating a peeling operation of a peeling robot according to an embodiment of the present disclosure.

Referring to FIGS. 5A, 5B, 6, 21, 22A, and 22B, a peeling robot PR peels off a protective film 30 from a transfer members 21 lifted up by the transport head 60. The peeling robot PR may peel off the protective film 30 from the transfer member 21 by using a tape having adhesiveness. Here, the adhesion of the tape may be stronger than the adhesion between the protective films 30 and the transfer members 21.

The peeling robot PR may be a robot having multiple joints. The peeling robot PR may freely move in the first, second, and third directions X, Y, and Z by using the multiple joints. An arm PR-a may be disposed at one end of the peeling robot PR. One end of the arm PR-a has means for picking up the tape, for example, tongs or a chuck. For example, one end of the arm PR-a may include tongs having first and second fingers PR-a1 and PR-2. The second finger PR-a2 may be larger in size than the first finger PR-2. The second finger PR-a2 supports the tape, and the first finger PR-1 presses the tape on the second finger PR-a1 so as to fix the tape on the second finger PR-a1 during the peeling operation of the peeling robot PR.

The tape may include a base TP-1 and an adhesive portion TP-2. The base TP-1 may have a larger area than the adhesive portion TP-2. The peeling robot PR may pick up the base TP-1 where the adhesive portion TP-2 is not disposed, and may discard the tape that has been used up to peel off the protective films 30 of the transfer members 21 into a collection bin (“TC” of FIG. 5A).

Alternatively, a chuck may be provided on one surface of the arm PR-a of the peeling robot PR. In this case, the chuck may adsorb the tape and place the adhesive surface of the tape into contact with the protective films 30 of the transfer members 21. Thereafter, the peeling robot PR may move in the downward direction and may thus peel the protective films 30 off of the transfer members 21. In this case, the adhesion of the tape needs to be stronger than the adhesion between the protective films 30 and stamp layers 220 of the transfer members 21, but weaker than the adsorption force of the chuck. The peeling robot PR may release the chuck function of the peeling robot PR and may thus discard the tape with the peeled-off protective films 30 attached thereto into the collection bin TC.

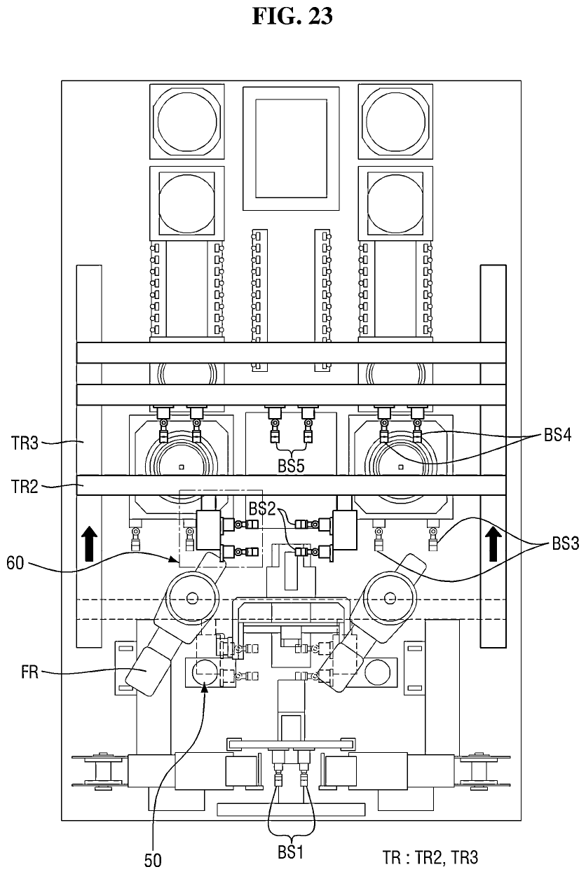

FIG. 23 is a schematic view illustrating the movement of the transport heads of the transfer equipment of FIGS. 5A and 5B.

Referring to FIG. 23, when protective films 30 are peeled off of transfer members 21 by the peeling robots PR, the transport heads 60 move near the stretching devices 80 along the transport rails TR. For example, the second transport rail TR2 slidably moves in the opposite direction of the first direction X along the third transport rails TR3.

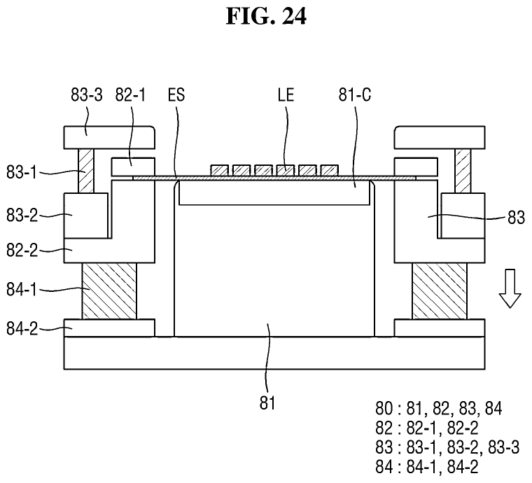

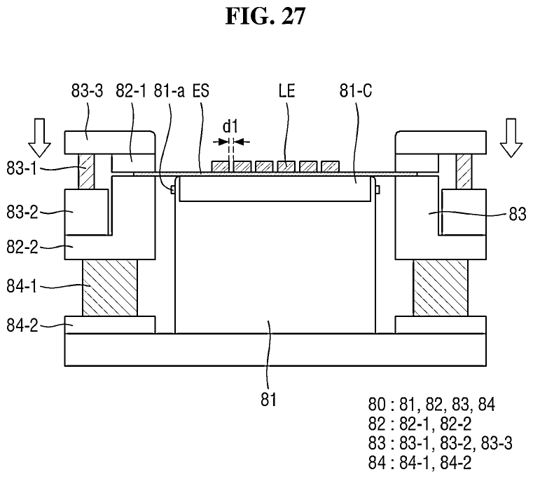

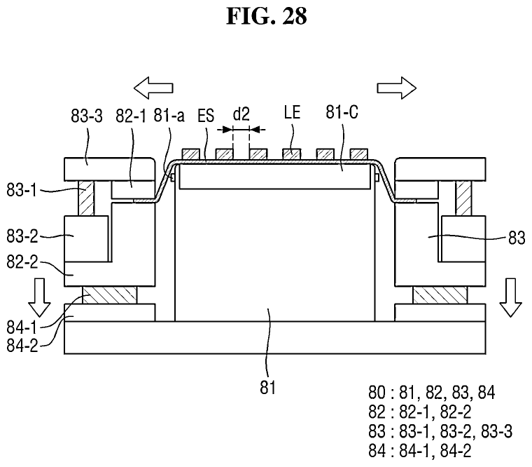

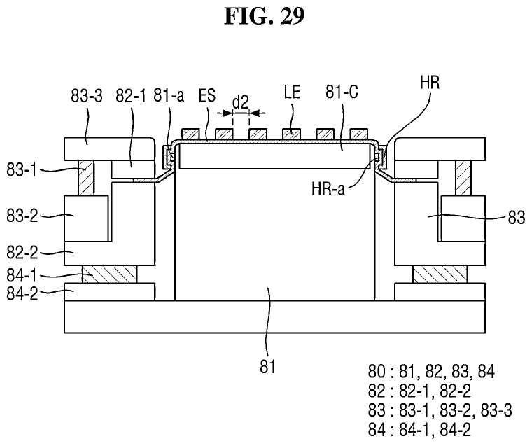

FIG. 24 is a front view of a stretching device according to an embodiment of the present disclosure. FIG. 25 is a cross-sectional view illustrating the structure of a transfer film according to an embodiment of the present disclosure. FIG. 26 is a side view of the transfer film of FIG. 25. FIGS. 27 through 29 are front views illustrating the operation of the stretching device of FIG. 24.

Referring to FIG. 24, a stretching device 80 may include a transfer film support unit 81, a fixing unit 82, a first mast unit 83, and a second mast unit 84.

The transfer film support unit 81 supports a transfer film ES.

Referring to FIG. 26, the transfer film ES may be formed of a stretchable elastic polymer material. The stretchable elastic polymer material may be, for example, polyolefin, polyvinyl chloride (“PVC”), elastomeric silicone, elastomeric polyurethane, or elastomeric polyisoprene. The transfer film ES may include a support layer ES-1 and an adhesive layer ES-2, which is disposed on the support layer ES-1. The support layer ES-1 may be formed of a material that is transparent enough to transmit light therethrough and has mechanical stability. For example, the support layer ES-1 may include a transparent polymer such as polyester, polyacrylic, polyepoxy, polyethylene, polystyrene, or polyethylene terephthalate. The adhesive layer ES-2 may include an adhesive material for bonding light-emitting elements LE. For example, the adhesive material may include urethane acrylate, epoxy acrylate, or polyester acrylate. The adhesive material may be a material whose adhesion changes in response to the application of ultraviolet (“UV”) light or heat thereto, and thus, the adhesive layer ES-2 can be easily separated from the light-emitting elements LE.

Referring to FIG. 25, a plurality of light-emitting elements LE are aligned on a transfer film ES, which is received in a transfer film cassette (“CA1” of FIG. 5B). A ring-type fixing frame 82-1 is disposed along the outer circumference of the transfer film ES.

The transfer film ES is provided from the transfer film cassette CA1 by a transport module (“TM” of FIG. 5B).

The transfer film ES with the light-emitting elements LE and the fixing frame 82-1 disposed thereon is accommodated in the transfer film cassette CA1 and is then transported.

The light-emitting elements LE are target objects to be transferred onto a circuit board 10.

The transfer film support unit 81 may include a fixing chuck 81-c, which is for fixing the transfer film ES. The fixing chuck 81-c may be one of an electrostatic chuck, an adhesive chuck, a vacuum chuck, and a porous vacuum chuck. The fixing chuck 81-c may adsorb and fix the transfer film ES onto a transport head (“60” of FIG. 5B). Accordingly, when the transport head 60 attaches the light-emitting elements LE to transfer members 21 and lifts up the transfer members 21, the transfer film ES may not be able to be lifted up together with the transfer members 21, but may be fixed to the transfer film support unit 81.

Referring again to FIG. 24, the fixing frame 82-1 forms a pair with a lower fixing part 82-2. The fixing frame 82-1 may also be referred to as an upper fixing part.

The fixing frame 82-1 and the lower fixing part 82-1, which form the fixing unit 82, may be formed as circular or polygonal (e.g., rectangular) panels or frames with circular or polygonal openings formed therein.

The first mast unit 83 is disposed adjacent to the fixing unit 82 and presses the fixing unit 82 in the opposite direction of the third direction Z (e.g., in the downward direction). Thus, the first mast unit 83 fixes the fixing unit 82 with the transfer film ES fixed thereto.

The first mast unit 83 may include a first inner mast part 83-1, a first outer mast part 83-2, and a pressing part 83-3.

The first inner mast part 83-1 and the first outer mast part 83-2 are disposed around the fixing unit 82.

The first inner mast part 83-1 is disposed on the first outer mast part 83-2 and is connected to a first lifting driving motor (not illustrated) to be movable in the third direction Z (e.g., in the upward direction) or in the opposite direction of the third direction Z.

When the first inner mast part 83-1 moves in the opposite direction of the third direction Z, the first inner mast part 83-1 may be inserted into the first outer mast part 83-2.

The pressing part 83-3 may be disposed on the first inner mast part 83-1.

The pressing part 83-3 is formed as a circular or polygonal (e.g., rectangular) panel or frame with a circular or polygonal opening formed therein.

Accordingly, when the first inner mast part 83-1 moves in the opposite direction of the third direction Z, the pressing part 83-3 also moves in the opposite direction of the third direction Z together with the first inner mast part 83-1.

The pressing part 83-3 protrudes toward the transfer film support unit 81, beyond the first inner mast part 83-1, and overlaps with the fixing unit 82.

When the pressing part 83-3 moves in the opposite direction of the third direction Z, the pressing part 83-3 presses the fixing frame 82-1. Accordingly, the fixing frame 82-1 and the lower fixing part 82-1 can fix the outer circumference of the transfer film ES.

The second mast unit 84 is disposed adjacent to the fixing unit 82 and the transfer film support unit 81. The second mast unit 84 may be disposed below the first mast unit 83 and the fixing unit 82.

The second mast unit 84 is disposed below the first mast unit 83 to move the first mast unit 83 in the opposite direction of the third direction Z and thus to stretch the width of the transfer film ES in an outer circumferential direction.

The second mast unit 84 may include a second inner mast part 84-1 and a second outer mast part 84-2.

The second inner mast part 84-1 and the second outer mast part 84-2 are disposed around the transfer film support unit 81.

The second inner mast part 84-1 is disposed on the second outer mast part 84-2 and is connected to a second lifting driving motor (not illustrated) to be movable in the third direction Z (e.g., in the upward direction) or in the opposite direction of the third direction Z.

When the second inner mast part 84-1 moves in the opposite direction of the third direction Z, the second inner mast part 84-1 may be inserted into the second outer mast part 84-2.

The first mast unit 83 and the fixing unit 82 are disposed on the second inner mast part 84-1. Accordingly, when the second mast part 84-1 moves in the opposite direction of the third direction Z, the first mast unit 83 and the fixing unit 82 may also move in the opposite direction of the third direction Z together with the second inner mast part 84-1.

The stretching device 80 may further include at least two vision units, i.e., one or more third vision units BS3 and one or more fourth vision units BS4 of FIG. 23.

The third vision units BS3 may be disposed adjacent to the transfer film support unit 81 and may accurately capture images of the distance between and the layout of light-emitting elements LE attached to a transport head 60. Also, the third vision units BS may accurately capture images of the locations of transfer members 21 attached to the transport head 60. A higher magnification is needed to capture an image of the distance between the light-emitting elements LE than to capture an image of the locations of the transfer members 21. Thus, the magnification of the third vision units BS3 may be appropriately changed depending on the purpose of use. Alternatively, one or more third vision units BS3 having different magnifications may be provided.

The fourth vision units BS4 may be disposed adjacent to the transfer film support unit 81 and may accurately capture images of the distance between and the layout of light-emitting elements disposed on the transfer film ES. Also, the fourth vision units BS4 may accurately capture images of the location of the transfer film ES on the stretching device 80. A higher magnification is needed to capture an image of the distance between the light-emitting elements LE than to capture an image of the location of the transfer film ES. Thus, the magnification of the fourth vision units BS4 may be appropriately changed depending on the purpose of use. Alternatively, one or more fourth vision units BS4 having different magnifications may be provided.

Referring to FIGS. 23 and 27 through 29, the transfer film support unit 81 supports the transfer film ES. A plurality of light-emitting elements LE are disposed on the transfer film ES to be a first distance d1 apart from one another.

When the pressing part 83-3 moves in the opposite direction of the third direction Z and presses the fixing unit 82, the fixing unit 82 fixes the outer circumference of the transfer film ES. When the fixing unit 82 fixes the outer circumference of the transfer film ES and the second mast unit 84 moves in the opposite direction of the third direction Z, the transfer film ES may be stretched two-dimensionally in the first and second directions X and Y. As the transfer film ES is stretched, the light-emitting elements LE bonded on the transfer film ES may become uniformly apart from one another by as much as a second distance d2. The second distance d2 may be greater than the first distance d1.

The stretching strength (or tensile strength) of the transfer film ES may be adjusted in accordance with a desired second distance d2 and may be, for example, about 120 gf/inch, but the present disclosure is not limited thereto.

One or more locking protrusions 81-a may be provided on the outside of the transfer film support unit 81 at regular intervals.

The locking protrusions 81-a may be formed along the circumference of the transfer film support unit 81.

The locking protrusions 81-a may be spaced apart at intervals of a predetermined distance along the circumference of the transfer film support unit 81.

A stopper HR is a ring-shaped member having locking grooves HR-a on the inside and may thus be coupled and fixed to the locking protrusions 81-a. As the locking grooves HR-a of the stopper HR are coupled and fixed to the locking protrusions 81-a, the transfer film ES can be prevented from being continuously stretched.

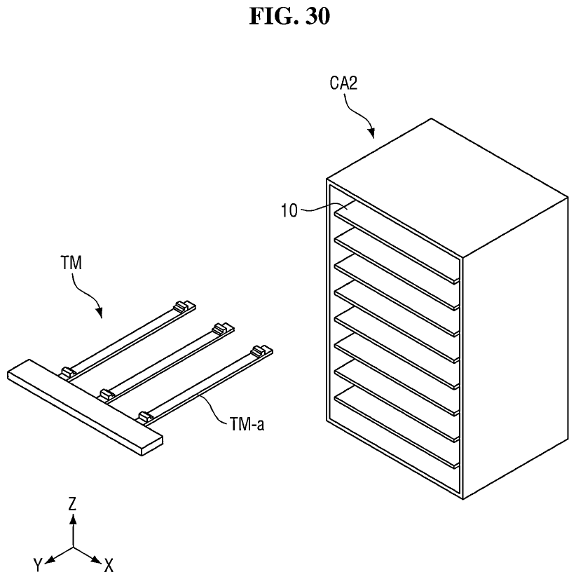

FIG. 30 is a perspective view illustrating how to transport circuit boards from a circuit board cassette with the use of a transport module according to an embodiment of the present disclosure.

Referring to FIG. 30, a circuit board cassette CA2, which accommodates a plurality of circuit boards 10 therein, may include a plurality of storage slots, in which the plurality of circuit boards 10 are placed. The storage slots may be arranged in a row in a vertical direction. The circuit boards 10 in the storage slots may be transported to a circuit board support member (“Mstg” of FIGS. 5A and 5B) by a transport module TM.

The transport module TM may include a plurality of support bars TM-a and a driving uni. The support bars TM-a may have a bar shape extending in one direction. The support bars TM-a may be spaced apart from one another at regular intervals.

The driving unit may move the support bars TM-a with a circuit board 10 placed thereon from the circuit board cassette CA2 to the circuit board support member Mstg. The driving unit may move the support bars TM-a in the vertical direction to a desired slot of the circuit board cassette CA2. Also, the driving unit may rotate the support bars TM-a or may move the support bars TM-a in a horizontal direction.

FIG. 30 illustrates how the transport module TM transports each circuit board 10 from the circuit board cassette CA2. A method to move each transfer film ES from the transfer film cassette CA1 to a stretching device 80 is similar to that illustrated in FIG. 30, and thus, a detailed description thereof will be omitted.

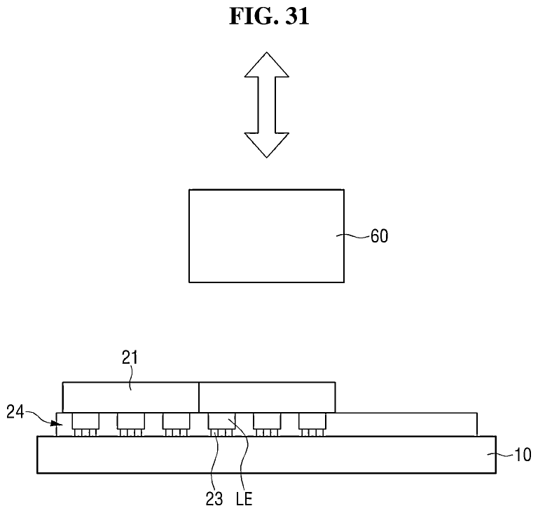

FIG. 31 is a schematic view illustrating how the transport head according to an embodiment of the present disclosure places light-emitting elements on a circuit board.

Referring to FIG. 31, a transport head 60 aligns light-emitting elements LE, which are attached on each of transfer members 21, on a circuit board 10 on a circuit board support member Mstg and detaches the transfer members 21. As a result, the light-emitting elements LE are transferred from the transfer members 21 to the circuit board 10.

For example, the transport head 60 transports each of the transfer members 21 with the light-emitting elements LE attached thereto to a desired location and detaches the transfer members 21 therefrom by releasing the adsorption of the transfer members 21.

The circuit board 10 may correspond to the substrate SUB of FIG. 4, which includes the TFT layer TFTL. The light-emitting elements LE may further include bonding electrodes 23 on surfaces thereof.

A flux 24 may be applied on the circuit board 10 to a predetermined thickness. The flux 24 may be a material for facilitating the bonding of the circuit board 10 and the bonding electrodes 23 during a pressure melting process using laser. The flux 24 may include a natural or synthetic rosin, which is either oil-soluble or water-soluble. The flux 24 may be in liquid form or in gel form. After the pressure melting process, the flux 24 is removed.

The flux 24 may preferably be applied to a thickness less than that of the light-emitting elements LE, but the thickness of the flux 24 may be the same as, or even greater than, the height of the light-emitting elements LE, in some regions, due to the arrangement of the light-emitting elements LE.

The transport head 60 transports each of the transfer members 21 with the light-emitting elements LE attached thereto to a desired location and detaches the transfer members 21 therefrom by releasing the adsorption of the transfer members 21. Accordingly, the light-emitting elements LE with transfer member attached are placed on the circuit board 10.

The circuit board 10 with the light-emitting elements LE disposed thereon may be received in the circuit board cassette CA2 by the transport module TM.

The circuit board support member Mstg may further include one or more fifth vision units (“BS5” of FIG. 23).

The fifth vision units BS5 may accurately capture images of the distance between, and the layout of, the light-emitting elements LE on the circuit board 10. Also, the fifth vision units BS5 may capture images of the location of the circuit board 10 on a stretching device (“80” of FIG. 5A or 5B). A higher magnification is needed to capture an image of the distance between the light-emitting elements LE than to capture an image of the location of the circuit board 10. Thus, the magnification of the fifth vision units BS5 may be appropriately changed depending on the purpose of use. Alternatively, one or more vision units BS5 having different magnifications may be provided.

However, the aspects of the disclosure are not restricted to the one set forth herein. The above and other aspects of the disclosure will become more apparent to one of daily skill in the art to which the disclosure pertains by referencing the claims, with functional equivalents thereof to be included therein.

What is claimed is:

1. A light-emitting element transfer system comprising:
a raw film cutting device configured to form a transfer member by cutting a raw film;
a stretching device configured to stretch a transfer film with a plurality of light-emitting elements disposed thereon;
a circuit board support member configured to support a circuit board; and
a transport head configured to adsorb the transfer member and transfer the light-emitting elements on the transfer film onto the circuit board by using the adsorbed transfer member.

2. The light-emitting element transfer system of claim 1, wherein
the transfer member includes a base layer and a stamp layer, which is disposed on one surface of the base layer, and
the stamp layer is formed of an adhesive or sticky material.

3. The light-emitting element transfer system of claim 2, wherein
the transfer member further includes a protective film, which is disposed on one surface of the stamp layer, and
the light-emitting element transfer system further includes a peeling robot configured to peel off the protective film of the transfer member adsorbed by the transport head.

4. The light-emitting element transfer system of claim 3, wherein
the peeling robot peels off the protective film from the stamp layer of the transfer member by using a tape having an adhesive surface, and
the light-emitting element transfer system further comprises a tape dispenser configured to provide the tape.

5. The light-emitting element transfer system of claim 3, wherein
the raw film cutting device includes a pedestal configured to support the raw film, a raw film transport unit disposed on opposite sides of the pedestal and configured to transport the raw film in a first direction, and a cutting unit configured to cut the raw film on the pedestal, and
the base layer, the stamp layer, and the protective film of the transfer member are sequentially disposed on the pedestal.

6. The light-emitting element transfer system of claim 5, wherein the raw film cutting device further includes a first vision unit configured to capture an image of the transfer member and the raw film on the pedestal.

7. The light-emitting element transfer system of claim 5, further comprising:
a reversing device configured to turn the transfer member upside down and left to right by adsorbing the protective film of the transfer member on the pedestal.

8. The light-emitting element transfer system of claim 7, wherein
the reversing device is rotatable 180 degrees about a rotational shaft, and
the reversing device further comprises a stage including a support chuck capable of adsorbing one surface of the transfer member.

9. The light-emitting element transfer system of claim 7, further comprising:
a first transport rail disposed under the pedestal and the raw film cutting device,
wherein the pedestal is movable along the first transport rail.

10. The light-emitting element transfer system of claim 7, wherein the transport head includes a body part movable along a second transport rail, a head chuck disposed on one surface of the body part and configured to adsorb or detach the transfer member, and at least one second vision unit configured to capture an image of the transfer member on the reversing device.

11. The light-emitting element transfer system of claim 10, wherein the second transport rail includes a first-direction transport rail extending in the first direction, a second-direction transport rail extending in a second direction, which is perpendicular to the first direction, and a third-direction transport rail extending in a third direction, which is perpendicular to the first and second directions.

12. The light-emitting element transfer system of claim 7, wherein the stretching device includes a transfer film support unit configured to support the transfer film with the light-emitting elements arranged thereon and having a cylindrical shape, a fixing unit configured to fix an outer circumference of the transfer film, a first mast unit configured to press the fixing unit in a third direction, and a second mast unit disposed below the first mast unit and configured to stretch a width of the transfer film in an outer circumferential direction by moving the first mast unit in the third direction.

13. The light-emitting element transfer system of claim 12, wherein the fixing unit includes a fixing frame disposed on a top surface of the outer circumference of the transfer film and a lower fixing part disposed on the second mast unit and overlapping with the fixing frame.

14. The light-emitting element transfer system of claim 12, wherein
the transfer film support unit includes locking protrusions formed along an outer side of the cylindrical shape, and
the stretching device further includes a ring-shaped stopper having locking grooves, which are coupled and fixed to the locking protrusions.

15. The light-emitting element transfer system of claim 12, wherein
the stretching device further includes one or more third vision units disposed adjacent to the transfer film support unit and configured to capture images of a distance between and a layout of the light-emitting elements attached to the transport head, and one or more fourth vision units disposed adjacent to the transfer film support unit and configured to capture images of a location of the transfer film on the transfer film support unit, and
each of the third vision units have a higher magnification than each of the fourth vision units.

16. The light-emitting element transfer system of claim 1, further comprising:
a transfer film cassette in which a storage space for accommodating the transfer film with the light-emitting elements disposed thereon is formed; and
a circuit board cassette having a storage space for accommodating the circuit board.

17. The light-emitting element transfer system of claim 16, further comprising:
a transport module including a forklift capable of loading an object thereon,
wherein
the transport module transports the transfer film from the transfer film cassette to the stretching device and transports the circuit board from the circuit board cassette to the circuit board support member by moving the forklift vertically and horizontally.

18. The light-emitting element transfer system of claim 1, further comprising:
a fifth vision unit configured to capture an image of at least one of a location of the circuit board on the circuit board support member, a distance between the light-emitting elements, and a layout of the light-emitting elements.

19. The light-emitting element transfer system of claim 1, wherein each of the light-emitting elements includes an n-type semiconductor, an active layer, a p-type semiconductor, a first contact electrode, and a second contact electrode.

20. The light-emitting element transfer system of claim 1, wherein the circuit board includes flux applied to one surface thereof.

21. A light-emitting element transfer system comprising:
a raw film cutting device configured to form a transfer member by cutting a raw film;
a reversing device configured to reverse the transfer member upside down and left-to-right;
a stretching device configured to stretch a transfer film with a plurality of light-emitting elements disposed thereon;
a circuit board support member configured to support a circuit board; and
a transport head configured to adsorb the transfer member and transfer the light-emitting elements on the transfer film onto the circuit board by using the adsorbed transfer member.

22. A light-emitting element transfer system comprising:
a raw film cutting device configured to form a transfer member by cutting a raw film in which a base layer, a stamp layer, and a protective layer are sequentially stacked;
a reversing device configured to reverse the transfer member upside down and left-to-right;
a transport head configured to lift the transfer member off from the reversing device by adsorbing the transfer member;
a peeling robot configured to peel off a protective film of the transfer member adsorbed to the transport head;
a stretching device configured to stretch a transfer film with a plurality of light-emitting elements disposed thereon; and
a circuit board support member configured to support a circuit board,
wherein the transport head transfers the light-emitting elements on the transfer film onto the circuit board by using the adsorbed transfer member.

23. A light-emitting element transfer system comprising:
a raw film cutting device configured to form a transfer member by cutting a raw film in which a base layer, a stamp layer, and a protective layer are sequentially stacked;
a reversing device configured to reverse the transfer member upside down and left-to-right;
a transport head configured to lift the transfer member off from the reversing device by adsorbing the transfer member;
a peeling robot configured to peel off a protective film of the transfer member adsorbed to the transport head;
a stretching device configured to stretch a transfer film with a plurality of light-emitting elements disposed thereon;
a circuit board support member configured to support a circuit board;
a transfer film cassette in which a storage space for accommodating the transfer film with the light-emitting elements disposed thereon is formed;
a circuit board cassette having a storage space for accommodating the circuit board; and
a transport module including a forklift capable of loading an object thereon,
wherein
the transport module transports the transfer film from the transfer film cassette to the stretching device and the circuit board from the circuit board cassette to the circuit board support member by moving the forklift vertically and horizontally, and
the transport head transfers the light-emitting elements on the transfer film onto a circuit board by using the transfer member with the protective film peeled therefrom.
